(19) United States
(12) Patent Application Publication
(10) Pub. No.: US 2013/0004261 A1
(43) Pub. Date: Jan. 3, 2013

(54) COATED FASTENER

(75) Inventors: Glen PATTINSON, Derby (GB); Michael ROBINSON, Sheffield (GB)

(73) Assignee: ROLLS-ROYCE PLC, London (GB)

(21) Appl. No.: 13/528,095

(22) Filed: Jun. 20, 2012

(30) Foreign Application Priority Data
Jun. 28, 2011 (GB) 1110939.4

(51) Int. Cl. F16B 33/06; C23C 16/44; C23C 16/06

(52) U.S. Cl. 411/366.1; 427/248.1; 427/249.18; 427/249.19; 427/249.1

(57) ABSTRACT

A first element (10) adapted to selectively engage a second element (20), wherein the first element comprises a coating (12) and at least an engaging portion (14) of the first element is coated in said coating, wherein the coating is formed by vapour deposition to provide a thermo-chemically stable layer for temperatures up to 800° C. The coating (12) may comprise one or more of a nitride, oxide or carbide of titanium, chromium or aluminium.

This invention relates to a coated element and particularly but not exclusively relates to a coated element for an engine, e.g. a gas turbine engine.

### BACKGROUND

Threaded fasteners have previously been coated in silver via electroplating since silver provides excellent anti-seize properties, including a low friction coefficient, low friction scatter, and high levels of reusability. For example, the silver may be applied to either, or both the internal and external threads of mechanical fasteners.

Alternatively, a number of dry film lubricants (DFLs) based on molybdenum disulphide, graphite, or lubricious oxides have been used. Like silver plating, DFLs can be applied to the internal and external threads of fasteners by means of dip, spray or brush coating with subsequent curing. These coatings also provide low friction surfaces.

Typically, the dimensions of the internal nut and external bolt threads are designed to accommodate coating thicknesses between 5 and 20 microns. Whilst this range is achievable in both the application of silver and DFLs, they may not be suited to smaller thicknesses.

Although silver provides excellent anti-seize properties, it is associated with significant corrosion problems, particularly when coating nickel or titanium alloys. For example, degradation of the coating in an engine environment can result in accelerated corrosion due to silver migration and/or the silver combining with sulphur and chlorine. Silver also has significant health concerns, both in terms of the plating process itself and as a contaminant within an engine.

The coating process for dry film lubricants on the other hand is subject to large variability and as such, these coatings do not provide the same level of performance or reusability as silver. Furthermore, DFLs also promote corrosion due to the elements or compounds used in the pigment or binder.

Seizure of threaded fasteners is commonly attributed to galling between the two substrates, and may be due to cold welding of the fastener constituents and/or due to chemical reactions taking place. Both silver and DFL coatings are used to provide a barrier to this, however their inherent properties result in deformation of the coating or chemical instability.

The present disclosure therefore seeks to address these issues.

### STATEMENTS OF INVENTION

According to a first aspect of the present invention there is provided a first element adapted to selectively engage a second element, wherein the first element comprises a coating and at least an engaging portion of the first element is coated in said coating, wherein the coating is formed by vapour deposition to provide a thermo-chemically stable layer for temperatures up to 800° C.

The coating may comprise one or more of a nitride, oxide or carbide of titanium, chromium or aluminium. For example, the coating may comprise one or more of titanium nitride, chromium nitride, aluminium nitride, titanium oxide, chromium oxide, aluminium oxide, titanium carbide, chromium carbide or aluminium carbide. The first element may be made from titanium.

The first and/or second elements may be elements for an engine, e.g. engine elements. For example, the first and second elements may be components of an engine, for example a gas turbine engine.

The coating may be suitable for use in high temperature environments, e.g. up to approximately 800° C. Accordingly, the first element, e.g. the coating, may be configured to operate in temperatures up to 800° C. The first element, e.g. the coating, may be configured to operate in temperatures greater than 50° C.

The first element may comprise a threaded portion adapted to engage a corresponding threaded portion of the second element. By way of example, the first element may comprise one of a nut or a bolt and the second element comprises the other of the nut or bolt.

The coating may be formed by Physical Vapour Deposition (PVD). Alternatively, the coating may be formed by Chemical Vapour Deposition (CVD).

The coating thickness may be between 0.5 and 50 microns. The first element may comprise one or more layers of coating.

An assembly may comprise the aforementioned first and second elements. The second element may comprise a coating. At least an engaging portion of the second element may be coated in said coating. The coating on the second element may be formed by vapour deposition, e.g. to provide a thermo-chemically stable layer for temperatures up to 800° C. The optional features described with respect to the first element may also apply to the second element. For example, the coating of the second element may comprise one or more of a nitride, oxide or carbide of titanium, chromium or aluminium and the second element may be made from titanium.

A turbomachine or gas turbine may comprise the aforementioned first element or the aforementioned assembly of first and second elements.

According to a second aspect of the present invention there is provided a method of manufacturing a first element adapted to selectively engage a second element, the method comprising: coating the first element by vapour deposition to provide a thermo-chemically stable layer for temperatures up to 800° C.

The method may comprise coating with one or more of a nitride, oxide or carbide of titanium, chromium or aluminium. The method may comprise coating by Physical Vapour Deposition (PVD) or by Chemical Vapour Deposition (CVD).

### BRIEF DESCRIPTION OF THE DRAWINGS

For a better understanding of the present invention, and to show more clearly how it may be carried into effect, reference will now be made, by way of example, to the accompanying drawings, in which:

FIG. 1 shows a nut and bolt assembly according to an example of the present disclosure.

### DETAILED DESCRIPTION

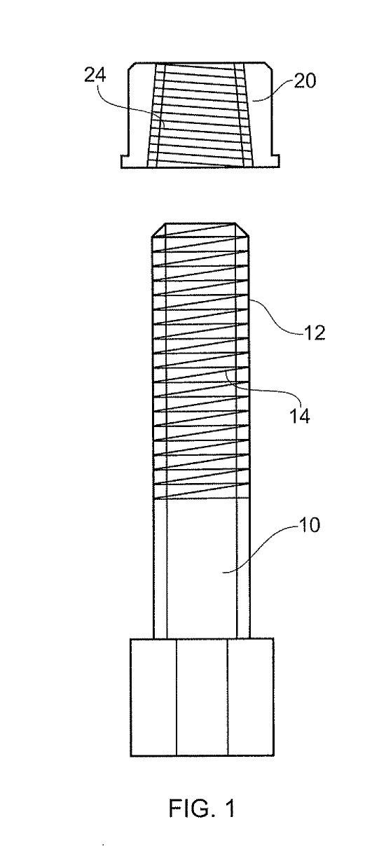

With reference to FIG. 1, a first element 10 according to an example of the present disclosure, may comprise a coating 12. The first element 10 may be adapted to selectively engage a second element 20. In the example shown, the first element 10 comprises a bolt and the second element 20 comprises a nut, although the first and second elements may comprise any fastener adapted for mutual engagement. The first and/or second elements may be made from titanium, nickel or any other alloy.

The first element 10 may comprise an engaging portion 14 which is adapted to engage a corresponding engaging portion 24 of the second element 20. In the example shown the engaging portions 14, 24 comprise corresponding threaded portions. For example, the engaging portion 14 may comprise a thread provided on an outer facing surface of the first element 10 and the engaging portion 24 may comprise a thread provided on an inner facing surface of the second element 20.

All or part of the engaging portion 14 of the first element 10 may be coated in said coating 12. Equally, the coated area may be concentrated on, but not restricted to the engaging portion 14 of the first element 10.

The engaging portion 24 of the second element 20 may alternatively or additionally to the first element be coated in the coating. Ail or part of the engaging portion 24 of the second element 20 may be coated in said coating. The coated area may be concentrated on, but not restricted to the engaging portion 24 of the second element 20.

The present invention involves the application of one or more coatings via a vapour deposition process, namely but not restricted to physical vapour deposition (PVD), or chemical vapour deposition (CVD). Coatings may be deposited onto the threaded components of nuts and bolts. This incorporates the coating of the entire nut/bolt, or the individual threaded sections of the nut/bolt, or combinations thereof.

Vapour deposition processes may be used for the deposition of high purity, thin film materials. The respective coating is grown on the substrate surface through the condensation of species from a vapour form. The method of vapour generation and mass transport differ between processes. As an example, physical vapour deposition can employ electron beam, sputtering, or cathodic arc means to evaporate the target material, which is subsequently transported in a vacuum to the substrate by an applied bias. Furthermore, ion doping may be used during the vapour deposition, e.g. to improve lubrication of the coating.

The coating 12 may consist of (although not limited to) nitrides, oxides or carbides of titanium, chromium, aluminium of any combination of these. Coating thicknesses may range between 0.5 and 50 microns. The coating may comprise a single layer or a plurality of layers. Each layer may comprise the same composition or the layers may have different compositions. Furthermore, each layer may be in a single phase or the layers may be in different phases such that they define multiphase morphologies.

In summary, the present disclosure relates to the application of hard and/or wear resistant coatings based on nitrides, oxides or carbides by vapour deposition techniques to either or both the internal and external threads of mechanical fasteners. The coatings may prevent seizure and provide significant reusability of mechanical fasteners operating in aggressive conditions, e.g. up to temperatures of around 800 ° C.

The above-described coating process specifically allows for the deposition of material types mentioned above which are capable of being temperature stable, corrosion resistant and adherent whilst not causing deformation of the substrate or interfering with the engineering tolerance of the part. This is presently not achievable through alternative coating application methods.

The use of coatings with higher thermal and chemical stability may provide a barrier to metal-metal contact, which may otherwise result in pressure welding or galling in engine conditions. The coating of the present invention may improve the hardness and wear resistance to prevent galling and fretting of the threads, which may ultimately result in seizure of the fastener. The deposition processes employed allow greater degree of control over prior processes to improve uniformity of coating thickness along threads on mechanical fasteners of varying sizes and also enhancing product repeatability.

Advantages of the coating of the present invention include: high temperature stability; chemical stability (and therefore better resistance to corrosion and galling); a known and repeatable coefficient of friction (and therefore a more reliably known stress required to tighten the bolts and more predictable overall clamping loads); elimination of the corrosion issues associated with silver on surrounding parts in the engine; and a significant reduction in coating thickness and quality variability,

The coatings of the present disclosure are further advantageous because they are uniform and adherent. Furthermore, the vapour deposition process used to apply the coating is repeatable and eliminates the health and safety issues associated with silver plating.

Coatings of the present disclosure may be used on a multitude of base alloys, which may be capable of being reused without the negative aspects associated with DFL's and silver.

The present disclosure is not restricted to components for engines, e.g. gas turbine engines or jet engines. The coatings disclosed herein may be applied in industrial applications, for example where anti seizure properties are required on fasteners, e.g. threaded fasteners. For example, the present disclosure may be applied to any application where the release of parts is required such as high temperature moulds or release agents.

1. A first element adapted to selectively engage a second element, wherein the first element comprises a coating and at least an engaging portion of the first element is coated in said coating, wherein the coating is formed by vapour deposition to provide a thermo-chemically stable layer for temperatures up to 800° C.

2. The first element of claim 1, wherein the coating comprises one or more of a nitride, oxide or carbide of titanium, chromium or aluminium.

3. The first element of claim 1, wherein the first element is made from titanium.

4. The first element of claim 1, wherein the first element comprises a threaded portion adapted to engage a corresponding threaded portion of the second element.

5. The first element of claim 1, wherein the coating thickness is between 0.5 and 50 microns.

6. The first element of claim 1, wherein the first element is configured to operate in temperatures greater than 50° C.

7. The first element of claim 1, wherein the coating is formed by Physical Vapour Deposition (PVD).

8. The first element of claim 1, wherein the coating is formed by Chemical Vapour Deposition (CVD).

9. The first element of claim 1, wherein the first element comprises one or more layers of coating.

10. An assembly comprising the first element and second element of claim 1, wherein the second element comprises a further coating and at least an engaging portion of the second element is coated in said further coating, wherein the further coating is formed by vapour deposition to provide a thermo-chemically stable layer for temperatures up to 800° C.

11. A turbomachine or gas turbine comprising the first element of claim 1.

12. A method of manufacturing a first element adapted to selectively engage a second element, the method comprising:
coating at least an engaging portion of the first element by vapour deposition to provide a thermo-chemically stable layer for temperatures up to 800° C.

13. The method of claim 12, wherein the method comprises coating the first element with one or more of a nitride, oxide or carbide of titanium, chromium or aluminium.

14. The method of claim 12, wherein the method comprises coating by Physical Vapour Deposition (PVD).

15. The method of claim 12, wherein the method comprises coating by Chemical Vapour Deposition (CVD).
